(19) United States
(12) Patent Application Publication
(10) Pub. No.: US 2010/0129961 A1
(43) Pub. Date: May 27, 2010

(54) MULTI CHIP STACKING WITH RELIABLE JOINING

(75) Inventors: AKIHIRO HORIBE, YOKOHAMA (JP); FUMIAKI YAMADA, YOKOHAMA (JP)

Correspondence Address: The Law Firm of Andrea Hence Evans, LLC, 14625 Baltimore Ave., #853, Laurel, MD, 20707, US

(73) Assignee: INTERNATIONAL BUSINESS MACHINES CORPORATION, ARMONK, NY (US)

(21) Appl. No.: 12/277,557

(22) Filed: Nov. 25, 2008

(51) Int. Cl. H01L 21/00

(52) U.S. Cl. 438/109; 257/E21.499

(57) ABSTRACT

The present invention relates to a method of multi chip stack bonding. A resin mixture is applied to a chip wafer and the chip wafer is heated until the resin mixture has solidified. The chip wafer is fragmented into individual chips and the individual chips are pre-stacked with alignment into a multi-chip stack in a joining process. Pressure and heating is applied to the multi-chip stack until the joining process is completed.

### CROSS REFERENCE TO RELATED APPLICATIONS

There are no cross-references related to this application.

### FIELD OF THE INVENTION

The present invention relates generally to semiconductor devices and more specifically to flip-chip bonding process for multi-chip stacking.

### BACKGROUND OF THE INVENTION

Semiconductor chips, depending on their application, are manufactured in multi-stacks having layers of chips stacked upon each other. Proper bonding methods and materials are used to maintain proper conduction and connection between the stacked chips.

### SUMMARY OF THE INVENTION

The present invention provides a method of multi chip stack bonding. A chip wafer is coated with a resin mixture. The chip wafer is heated until the coated resin mixture has solidified. The chip wafer is fragmented into individual chips and the individual chips are pre-stacked with alignment into a multi-chip stack. The pre-stacking process may be done at a temperature which is lower than the melting point of the bumps or solder balls of the individual chips. Pressure is applied to the multi-chip stack while heating the multi-chip stack in a joining process. The heating of the multi-chip stack is continued until the joining process is completed.

### BRIEF DESCRIPTION OF THE DRAWINGS

The features and advantages of aspects of the present invention will become more apparent from the detailed description set forth below when taken in conjunction with the claims and drawings, in which like reference numbers indicate identical or functionally similar elements or steps. Additionally, the left-most digit of a reference number identifies the drawing in which the reference number first appears.

FIGS. 1A-1C illustrate a chip wafer undergoing treatment and fragmentation in accordance with an aspect of an embodiment of the present invention.

FIGS. 2A-2B illustrate a multi-chip stack being produced in accordance with an aspect of an embodiment of the present invention.

### DETAILED DESCRIPTION OF THE INVENTION

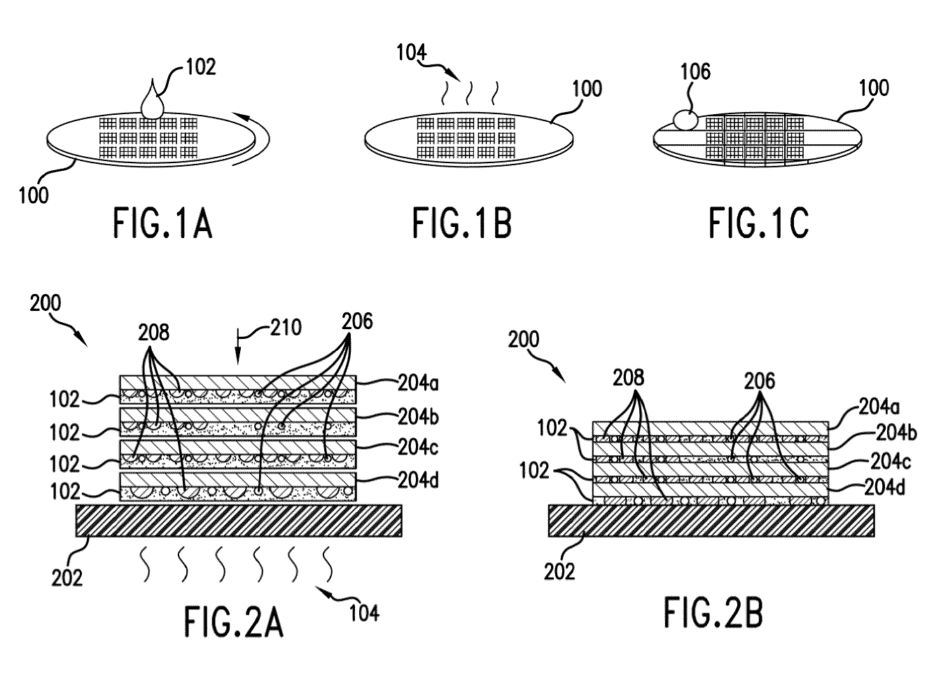

Referring now to FIG. 1A, a chip wafer 100 undergoing treatment according to an aspect of an embodiment of the present invention is shown. Resin 102 is applied to chip wafer 100. In one aspect or an embodiment of the present invention, epoxy resin is used and applied onto chip wafer 100. The resin application may be done, for example, by using a spin coating method. In another aspect of an embodiment of the present invention, chip wafer 100 is spun at about 3000 rpm until resin 102 is uniformly distributed over chip wafer 100. In another aspect of an embodiment of the present invention, resin 102 may contain resin hardener that belongs to a group such as carboxylic acid. In another aspect of an embodiment of the present invention, resin 102 may have a liquid encapsulation composition including a hardening accelerator and solvent. In yet another aspect of an embodiment of the present invention, resin 102 may be an imide series resin. In yet another aspect of an embodiment of the present invention, thermoplastic resin may be added to resin 102 in order to reduce brittleness of resin 102 during temporary hardening of resin 102.

Referring now to FIG. 1B, a chip wafer 100 undergoing additional treatment according to an aspect of an embodiment of the present invention is shown. Chip wafer 100, having resin 102 uniformly distributed on it as shown in the previous Figure, is subjected to heating from heating source 104 for a period of time. The heating is continued until resin 102 has solidified. In an aspect of an embodiment of the present invention, resin 102 may be epoxy resin containing a hardening agent with a flux function that has a high melting point, has low solubility for a solvent to be added below the heating temperature of epoxy resin 102, and has at least one aromatic series hydroxyl group and aromatic series carboxyl group. In this aspect of an embodiment of the present invention, a hardener having these characteristics helps avoid excessive reaction during the heating process shown in FIG. 1B.

Referring now to FIG. 1C, chip wafer 100 undergoing further treatment according to an aspect of an embodiment of the present invention is shown. Chip wafer 100, following the solidification of resin 102, is fragmented into individual chips. In one aspect of an embodiment of the present invention, the fragmentation may be done using a dicer, bonder 106 or similar tool, machinery or device.

Referring now to FIG. 2A, a multi-chip stack 200 being produced in accordance with an embodiment of the present invention is shown. Individual chips 204a-204d previously produced by the fragmentation process of chip wafer 100 are stacked upon one another and chip substrate 202 as shown. In one aspect of an embodiment of the present invention, resin 102 may include spacer particles 206 that have a homogeneous grain size. In another aspect of an embodiment of the present invention, spacer particles 206 are of a specific grain size equivalent to the desired height between chips and the substrate. In yet another aspect of an embodiment of the present invention, spacer particles 206 may have a grain size that is smaller than the height of a chip's bump electrode or solder ball 208 before the chips are stacked. In yet another aspect of an embodiment of the present invention, minute particles such as glass may be added to resin 102 in order to reduce resin 102's thermal expansion coefficient. These minute particles may have a low thermal expansion coefficient and have a grain size that is smaller than those of spacer particles 206.

In yet another aspect of an embodiment of the present invention, spacer particles 206 may be inorganic particulates such as silica and aluminum nitride. In yet another aspect of an embodiment of the present invention spacer particles 206 may be cross-linked particles of sufficient elastic modulus that have a spacing function even at a joining temperature such as that of divinylbenzene. In yet another aspect of an embodiment of the present invention, spacer particles 206 may be shell particles with inorganic material for the core and a resin layer for the shell. In a further aspect of an embodiment of the present invention, resin 102 may include bumps or solder balls 208 which are used for bonding the different chip layers of multi-chip stack 200. In a further aspect of an embodiment of the present invention, the grain size of spacer particles 206 may be in the range of 1 to 100 um. The grain size of spacer particles 206 may also be adjusted by a required bump height. In a further aspect of an embodiment of the present invention, if the shape of bumps or solder balls 208 before joining is a ball-type, the diameter of spacer particle 206 would be about 70% of the diameter of bumps 208.

Pressure is applied by pressure source 210 while multi-chip stack 200 is subjected to heating by heating source 104. Both pressure and heating may be applied by a thermo-compression device. III one aspect of an embodiment of the present invention, pressure may be applied using a flip chip bonder or device. In another aspect of an embodiment of the present invention, multi-chip stack 200 is subjected to a temperature which is lower than the joining temperature of bumps or solder balls 208. When joining or stacking the chips, stacking is made possible without injecting or applying sealant. The joining process may entail sequentially stacking each individual chip 204a-d, aligning the chips in the stack and thermo compressing the stack. In another aspect, the joining process may entail stacking individual chips 204a-d sequentially, and thermo compressing each stacked chip after the chip as been aligned onto the stack.

In one aspect of an embodiment of the present invention, because resin 102 has a flux function, no process of separate flux application and washing is required. In another aspect of an embodiment of the present invention, the temperature could be 20-40 degrees C. over the melting temperature of solder balls or bump 208. Where lead-free solder such as Sn—Ag is used, the melting temperature is around 220 degrees C.

In one aspect of an embodiment of the present invention, individual chips 204a-204d may be stacked without having solder balls or bumps 208 melted. Bumps 208 are contacted physically once the resin is cured. In another aspect of an embodiment of the present invention, solder balls or bumps 2()8 are melted in the stacking process thereby contributing or assisting the bonding process.

Referring now to FIG. 2B, a multi-chip stack 200 produced in accordance with an embodiment of the present invention is shown. Spacer particles 206 are shown maintaining their grain sizes while also maintaining the desired height between chips 204a-d. Once resin 102 has cured, thermo compression by pressure source 210 and heating source 104, respectively, is discontinued. Resin 102 completely covers the electrode surface between the chips in multi-chip stack 200 and has a sealing effect, which in turn prevents corrosion. The number of bumps or solder balls 208 crushed during the process is significantly reduced because of the shortened time used for mounting or stacking.

In one aspect of an embodiment of the present invention, solder balls or bumps 208 are melted and joined before the resin application and curing process. This results in obtaining a reliable joint between the chips in multi-chip stack 200.

In another aspect of an embodiment of the present invention, multi-chip stack 200 is arranged or aligned to achieve good joining of many small bumps or solders balls 208 between the stacked chips. This is done in order to prevent chip dislocation.

In yet another aspect of an embodiment of the present invention, individual chips 204a-d are pre-stacked sequentially with pressure, heating and alignment. The temperature during this pre-stacking process may be lower than the melting point of bumps or solder balls 208. As an example, if the multi-chip stack joining temperature is 260 degrees C., the pre-stacking temperature may be somewhere between 100 and 200 degrees C. In one aspect of an embodiment of the present invention, the pre-stacking temperature may be room temperature. Multi-chip stack is subjected to pressure and, upon joining, an elevated joining temperature which is maintained until the joining process is completed. In another aspect, the aligning and joining process may be performed for each individual chip.

The invention has been described in detail with particular reference to certain preferred embodiments thereof, but it will be understood that variations and modifications can be effected within the spirit and scope of the invention.

The invention claimed is:

1. A method of multi chip stack bonding, comprising:
coating a chip wafer with a resin mixture:
heating said chip wafer until said resin mixture has solidified;
fragmenting said chip wafer into individual chips;
pre-stacking said individual chips with alignment into a multi-chip stack at a temperature lower than the melting point of solder bumps of said individual chips; and
applying pressure to said multi-chip stack while heating said multi-chip stack, in a joining process, wherein said heating is continued until said joining process is completed.
